(19) United States
(12) Patent Application Publication
(10) Pub. No.: US 2026/0358449 A1
(43) Pub. Date: Nov. 12, 2026

(54) Component Analysis Device

(71) Applicant: Hitachi High-Tech Corporation, Minato-ku, Tokyo (JP)

(72) Inventor: Yoshiki YONAMOTO, Tokyo (JP)

(21) Appl. No.: 19/129,742

(22) PCT Filed: Oct. 17, 2023
(86) PCT No.: PCT/JP2023/037537

§ 371 Date: May 14, 2025

(30) Foreign Application Priority Data
Dec. 7, 2022 (JP) 2022-195770

(51) Int. Cl. G01R 33/30; G01R 33/32; G01R 33/34

(52) U.S. Cl. CPC G01R 33/30; G01R 33/323; G01R 33/34092

(57) ABSTRACT

In a component analysis device using an optical nuclear magnetic resonance phenomenon, it is possible to measure a sample having a wider range of configurations, and it is not necessary to adjust an objective lens when exchanging the sample. The component analysis device using an optical nuclear magnetic resonance phenomenon includes: a diamond having an electron spin on an NV center that causes an electron spin resonance phenomenon; a microwave irradiation substrate on which the diamond is disposed and which irradiates the diamond with a microwave; an objective lens configured to irradiate the diamond with laser light and detect fluorescence emitted from the NV center in response to the irradiation with the laser light; and a magnet configured to apply a static magnetic field to the NV center. The microwave irradiation substrate includes a light transmission unit configured to allow the laser light and the fluorescence to transmit.

### TECHNICAL FIELD

The present invention relates to a component analysis device, and more particularly to a component analysis device using an optical nuclear magnetic resonance phenomenon.

### BACKGROUND ART

In recent years, an optical nuclear magnetic resonance technique using a diamond has been proposed. An electron spin present on a nitrogen-vacancy complex defect (referred to as an NV center) present in the diamond has a property of emitting red fluorescence when absorbing light having a wavelength of about 532 nm. In addition, in a case where there is no static magnetic field applied from the outside, when the electron spin is irradiated with a microwave of about 2.87 GHz, the electron spin absorbs the microwave and enters an excited state. Accordingly, an intensity of the red fluorescence emitted when the electron spin is irradiated with the light having a wavelength of about 532 nm decreases. This is referred to as an electron spin resonance phenomenon.

On the other hand, when a static magnetic field is applied from the outside, since the frequency of the microwave to be absorbed changes according to a value of the applied static magnetic field, the frequency of the microwave at which the electron spin resonance phenomenon occurs changes from about 2.87 GHz. Therefore, an intensity of the magnetic field felt by the NV center in the diamond can be quantified by measuring frequency dependence of the intensity of the red fluorescence when irradiated with the light having a wavelength of about 532 nm on the microwave to be emitted.

Further, since the microwave and the irradiation light having a wavelength of about 532 nm are emitted in a pulsed manner rather than continuously in time, the intensity of the magnetic field can be detected with higher sensitivity. When this pulse irradiation method is used, it is possible to selectively detect not only a static magnetic field but also an alternating magnetic field with a specific frequency.

Here, when a molecule containing hydrogen, fluorine, or the like is present near the NV center in the diamond, an alternating nuclear magnetic field formed by nuclei of hydrogen, fluorine, or the like is detected. This detection of the nuclear magnetic field is a nuclear magnetic resonance method, and in the present description, this is referred to as an optical nuclear magnetic resonance method in order to distinguish from other nuclear magnetic resonance methods (normal nuclear magnetic resonance method or normal nuclear magnetic resonance method in the related art). In the optical nuclear magnetic resonance method, a frequency of the nuclear magnetic field can be calculated by converting a temporal change of the detected alternating nuclear magnetic field into the frequency. Based on this frequency, a molecular structure of the molecule containing hydrogen, fluorine or the like can be determined. In addition, an abundance of the molecule can be quantified based on a magnitude of the detected nuclear magnetic field. It is known that this optical nuclear magnetic resonance method is superior in detection sensitivity to other nuclear magnetic resonance methods.

NPL 1 describes a disposition diagram of optical nuclear magnetic resonance in which a diamond including an NV center is disposed on a circuit substrate that emits microwaves, a liquid measurement sample containing hydrogen is provided on the diamond, light having a wavelength of about 532 nm is emitted via an objective lens disposed directly above the measurement sample, red fluorescence emitted from the NV center in the diamond is also detected through the objective lens, and thus a nuclear magnetic field formed by hydrogen nuclei in the measurement sample is detected.

In NPL 1, by using the liquid measurement sample, the light having a wavelength of about 532 nm is transmitted through the measurement sample from the objective lens immediately above, the NV center immediately below is irradiated with the light, and the red fluorescence emitted from the NV center is also transmitted through the measurement sample and detected via the objective lens.

### CITATION LIST

### Non Patent Literature

[NPL 1] “Construction and operation of a tabletop system for nanoscale magnetometry with single nitrogen-vacancy centers in diamond”, AIP Advances 10, 025206 (2020), full text

### SUMMARY OF INVENTION

### Technical Problem

However, in the related art, there is a problem that a configuration of a measurable sample is limited. Further, in the related art, there is a problem that it is necessary to adjust the objective lens every time the sample is exchanged.

For example, in the optical nuclear magnetic resonance method in the related art, the measurement sample is limited to a liquid through which the light of about 532 nm and the red fluorescence are transmitted, or a thin film sample close to optically transparent.

That is, in a detection disposition of the optical nuclear magnetic resonance method in the related art, it is difficult to measure a solid sample such as a general resin. This is because, since a solid sample such as a resin is generally optically opaque, the light having a wavelength of about 532 nm emitted via the objective lens disposed immediately above the measurement sample is blocked by the measurement sample and cannot reach the NV center present immediately below the measurement sample in the diamond, and the NV center does not emit the red fluorescence.

In addition, in the detection disposition of the optical nuclear magnetic resonance method in the related art (the objective lens is disposed directly above the measurement sample placed on the diamond), a distance between a surface of the diamond and the objective lens is limited by a working distance of the objective lens. Therefore, a thickness of the measurement sample needs to be smaller than the distance between the diamond and the objective lens, and a form of the measurement sample is limited.

Further, in the detection disposition of the optical nuclear magnetic resonance method in the related art, when exchanging the measurement sample, it is necessary to change a height of the objective lens and keep the objective lens away from the measurement sample. Therefore, it is necessary to re-adjust the distance between the objective lens and the measurement sample after placing a new measurement sample, and thus it takes time to exchange the sample. In addition, the detection sensitivity may easily decrease depending on the degree of adjustment.

As described above, in the optical nuclear magnetic resonance method in the related art, a measurement sample having a wider range of materials or a thicker measurement sample cannot be a measurement target, and it is necessary to adjust the height of the objective lens when exchanging the measurement sample.

The invention has been made in view of the above problems, and an object of the invention is to make it possible to measure a sample having a wider range of configurations and to make it unnecessary to adjust an objective lens when exchanging the sample in a component analysis device using an optical nuclear magnetic resonance phenomenon.

### Solution to Problem

An example of a component analysis device according to the invention includes a microwave irradiation substrate that irradiates a diamond with microwaves, and the microwave irradiation substrate includes a light transmission unit that allows laser light and fluorescence to transmit.

The present description includes disclosed contents of Japanese Patent Application No. 2022-195770 which is the basis of the priority of the present application.

### Advantageous Effects of Invention

With the component analysis device using the optical nuclear magnetic resonance phenomenon according to the invention, it is possible to measure a sample having a wider range of configurations, and it is not necessary to adjust an objective lens when exchanging the sample.

### BRIEF DESCRIPTION OF DRAWINGS

FIG. 1 is a diagram showing a structure of a microwave irradiation substrate according to Embodiment 1 of the invention.

FIG. 2 is a diagram showing a disposition order of components in Embodiment 1.

FIG. 3 is a diagram showing a disposition order of components when a microwave irradiation substrate in the related art is used.

FIG. 4 is a flowchart showing an execution order of optical nuclear magnetic resonance measurement when the microwave irradiation substrate in FIG. 1 is used.

FIG. 5 is a flowchart showing an execution order of optical nuclear magnetic resonance measurement when the microwave irradiation substrate in the related art is used.

FIG. 6 is a graph showing a relationship between an intensity of a microwave emitted from a light transmission unit of the microwave irradiation substrate in FIG. 1 and a frequency of the introduced microwave.

FIG. 7 is a graph showing a relationship between a microwave wavelength and a length from a feeding point to a loop center when the intensity of the microwave emitted from the light transmission unit of the microwave irradiation substrate in FIG. 1 is maximized.

FIG. 8 is a graph showing a relationship between a maximum value of the intensity of the microwave emitted from the light transmission unit of the microwave irradiation substrate in FIG. 1 and an interconnect thickness.

FIG. 9 is a graph showing a relationship between the maximum value of the intensity of the microwave emitted from the light transmission unit of the microwave irradiation substrate in FIG. 1 and a distance between an interconnect and an electrode facing each other.

FIG. 10 is a graph showing a relationship between the maximum value of the intensity of the microwave emitted from the light transmission unit of the microwave irradiation substrate in FIG. 1 and an inner diameter of the light transmission unit.

### DESCRIPTION OF EMBODIMENTS

Hereinafter, embodiments of the invention will be described with reference to the drawings.

### Embodiment 1

In a component analysis device using an optical nuclear magnetic resonance phenomenon according to Embodiment 1, a microwave irradiation substrate is provided with a light transmission unit and provided in an optical nuclear magnetic resonance device, and a disposition of a measurement sample, a diamond, the microwave irradiation substrate, and an objective lens in this order is prepared.

According to the present embodiment, the measurement sample can be placed on the diamond without moving the objective lens.

According to the present embodiment, light having a wavelength of about 532 nm emitted via the objective lens and red fluorescence emitted from an NV center in the diamond can be transmitted through the light transmission unit of the microwave irradiation substrate. Further, the microwave with which the NV center in the diamond is irradiated is emitted from the light transmission unit of the microwave irradiation substrate.

Therefore, according to the present embodiment, since the disposition of the measurement sample, the diamond, the microwave irradiation substrate, and the objective lens in this order can be implemented, it is possible to measure a measurement sample having a larger thickness and a wider range of optical properties, and it is not necessary to adjust the objective lens when exchanging a sample. Therefore, a form of the sample that can be measured by optical nuclear magnetic resonance is expanded, and a variation in a measured value due to the adjustment of the objective lens can be reduced, which leads to expansion of an application of optical nuclear magnetic resonance measurement and improvement of reliability of measurement data.

Although FR-4 (glass epoxy material) is used as a substrate material of the microwave irradiation substrate used in the present embodiment, other materials such as alumina and silicon nitride may be used. In addition, although copper is used as a material of an interconnect portion, an electrode portion, and a loop portion formed on the microwave irradiation substrate, gold or another metal may be used. Further, the light transmission unit may be an opening, or a material such as glass that allows the light having a wavelength of about 532 nm or the red fluorescence to transmit may be used. Furthermore, a disposition direction of the measurement sample, the diamond, the microwave irradiation substrate, and the objective lens is not limited as long as the measurement sample, the diamond, the microwave irradiation substrate, and the objective lens are disposed in this order. For example, it is not always necessary to dispose the measurement sample at the top, and the objective lens may be disposed above.

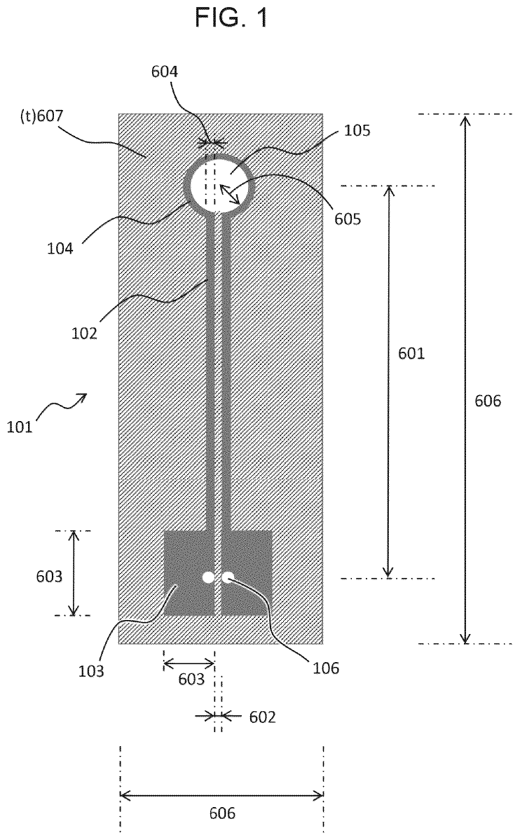

Hereinafter, a more specific configuration according to Embodiment 1 will be described with reference to FIGS. 1 to 10. First, FIG. 1 will be described. FIG. 1 is a diagram showing a structure of the microwave irradiation substrate according to Embodiment 1.

The component analysis device includes a microwave irradiation substrate 101. The microwave irradiation substrate 101 includes a conductive portion, and the conductive portion includes an interconnect 102, a pair of electrodes 103, a loop 104, and a feeding point 106. The pair of electrodes 103 are connected to each other via the interconnect 102 and the loop 104. By providing such a conductive portion, it is possible to radiate a microwave. In addition, the microwave irradiation substrate 101 includes a light transmission unit 105.

Here, in the present embodiment, the electrodes 103 are not distinguished in positive and negative. In addition, a shape of the loop 104 is preferably a circular shape (for example, a perfect circular shape, or more precisely, a shape having an arc-shaped portion) in order to reduce radiation unevenness of the microwave, but is not necessarily to be a circular shape, and may be another structure such as a square or a rhombus. Further, the interconnect 102 serves as a waveguide of a microwave introduced from the electrode 103 via the feeding point 106. A shape of the interconnect 102 is preferably a linear shape since unnecessary reflection of the introduced microwave may occur when the interconnect 102 is folded or bent.

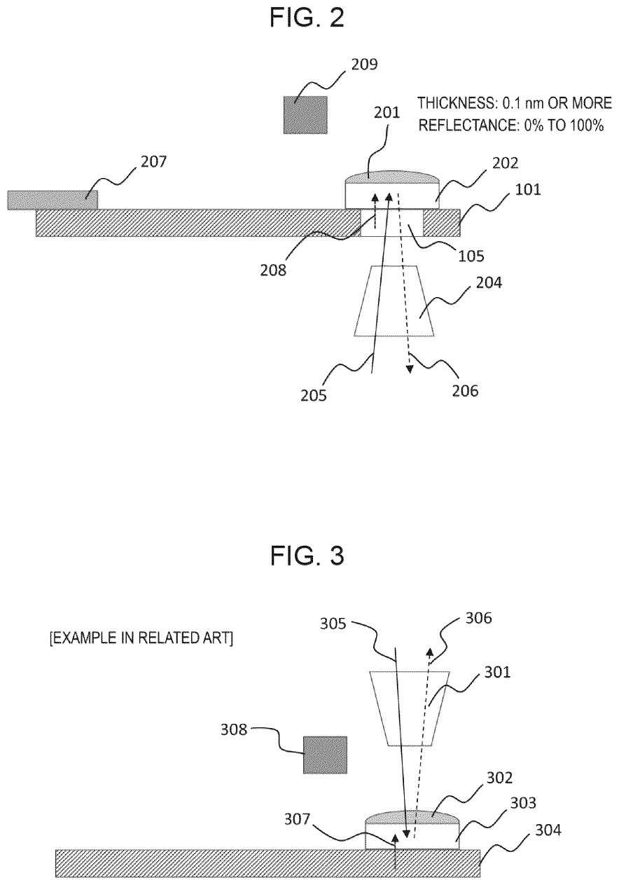

Next, FIG. 2 will be described. FIG. 2 is a diagram showing a disposition order of components in Embodiment 1. With respect to the microwave irradiation substrate 101, a measurement sample 201, a diamond 202, the microwave irradiation substrate 101, and an objective lens 204 are disposed in this order.

The microwave irradiation substrate 101 is used as a structure for disposing the diamond 202, and irradiates the diamond 202 with a microwave. The diamond 202 is configured to allow the measurement sample 201 to be placed thereon. According to such a configuration, other structures and the like for placing the measurement sample 201 are unnecessary.

Light 205 (laser light) having a wavelength of about 532 nm is emitted from a laser light source (not shown). The objective lens 204 irradiates the diamond 202 with the light 205 having a wavelength of about 532 nm. With the light 205 having a wavelength of about 532 nm emitted via the objective lens 204, a NV center in the diamond 202 is irradiated via the light transmission unit 105. Here, the light transmission unit 105 allows the light 205 having a wavelength of about 532 nm to transmit.

The diamond 202 has an electron spin on the NV center that causes an electron spin resonance phenomenon. In response to the irradiation with the light 205 having a wavelength of about 532 nm, red fluorescence 206 is emitted from the NV center. The red fluorescence 206 has a wavelength in a range, for example, of 600 nm to 700 nm, but is not limited thereto. In a modification, fluorescence that is not red may be emitted.

The light transmission unit 105 allows the red fluorescence 206 to transmit. After being transmitted through the light transmission unit 105, the red fluorescence 206 is detected by a detection device (not shown) via the objective lens 204. In this manner, the objective lens 204 causes the detection device to detect the red fluorescence 206.

A connector 207 is for forming the feeding point 106 on the electrode 103. Instead of the connector 207, another structure may be used as long as the feeding point 106 can be formed by wire bonding or the like. In addition, the diamond 202 is irradiated with a microwave 208 via the light transmission unit 105.

Here, regarding the disposition of the diamond 202, a center thereof does not need to coincide with a center of the light transmission unit 105, and it is sufficient that the diamond 202 is disposed in a manner of being capable of being irradiated with the light 205 having a wavelength of about 532 nm from the objective lens 204. However, the same region (measurement target region) in the diamond 202 is simultaneously irradiated with the light 205 having a wavelength of about 532 nm and the microwave 208. Such simultaneous irradiation can cause the electron spin resonance phenomenon in the NV center.

In addition to the disposition described above, the component analysis device includes a static magnetic field applying magnet 209 for applying a static magnetic field to the NV center. The static magnetic field applying magnet 209 is provided near the diamond 202, thereby enabling the optical nuclear magnetic resonance measurement. Here, the static magnetic field applying magnet 209 is not necessarily a permanent magnet, and may be an electromagnet.

Next, FIG. 3 will be described. FIG. 3 is a diagram showing a disposition order of components when a microwave irradiation substrate in the related art is used. An objective lens 301, a measurement sample 302, a diamond 303, and a microwave irradiation substrate 304 are disposed in this order.

Light 305 having a wavelength of about 532 nm emitted via the objective lens 301 is transmitted through the measurement sample 302, and a NV center in the diamond 303 is irradiated with the light 305. A red fluorescence 306 emitted from the NV center is transmitted through the measurement sample 302, and is detected via the objective lens 301.

A circuit capable of emitting a microwave 307, for example, a coplanar circuit, is formed on the microwave irradiation substrate 304, and the same position on the diamond 303 is irradiated with the light 305 having a wavelength of about 532 nm and the microwave 307.

In addition to the disposition described above, a static magnetic field applying magnet 308 is provided near the diamond 303, and the optical nuclear magnetic resonance measurement is enabled.

Here, as described above, the measurement sample 302 that can be measured with the configuration in the related art is limited to a liquid sample or a thin film sample that can allow the light 305 having a wavelength of about 532 nm and the red fluorescence 306 to transmit.

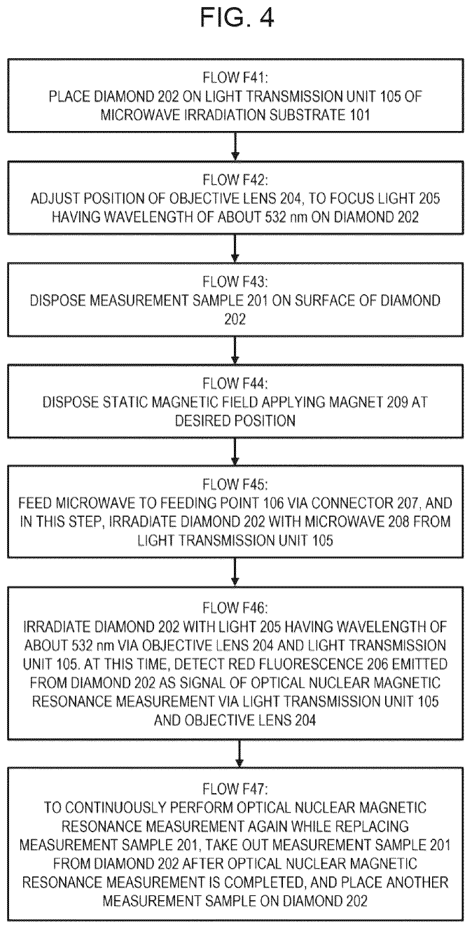

Next, FIG. 4 will be described. FIG. 4 is a flowchart showing an execution order of optical nuclear magnetic resonance measurement when the microwave irradiation substrate according to Embodiment 1 is used.

In a flow F41, the diamond 202 is placed on the light transmission unit 105 of the microwave irradiation substrate 101. In a flow F42, a position of the objective lens 204 is adjusted to focus the light 205 having a wavelength of about 532 nm on the diamond 202. Subsequently, in a flow F43, the measurement sample 201 is disposed on a surface of the diamond 202. In a flow F44, the static magnetic field applying magnet 209 is disposed at a desired position.

In a flow F45, a microwave is fed to the feeding point 106 via the connector 207, and in this step, the diamond 202 is irradiated with the microwave 208 from the light transmission unit 105. Subsequently, in a flow F46, the diamond 202 is irradiated with the light 205 having a wavelength of about 532 nm via the objective lens 204 and the light transmission unit 105. At this time, the red fluorescence 206 emitted from the diamond 202 is detected as a signal of the optical nuclear magnetic resonance measurement via the light transmission unit 105 and the objective lens 204.

When the optical nuclear magnetic resonance measurement is continuously performed again while replacing the measurement sample 201 after the completed of the optical nuclear magnetic resonance measurement, it is sufficient the measurement sample 201 taken out from the diamond 202 and another measurement sample is placed on the diamond 202, as in a flow F47. Thereafter, it is possible to proceed to the optical nuclear magnetic resonance measurement in the flow F46 without re-executing the flow F42.

Here, the order of the flow F42, the flow F43, and the flow F44 may be changed.

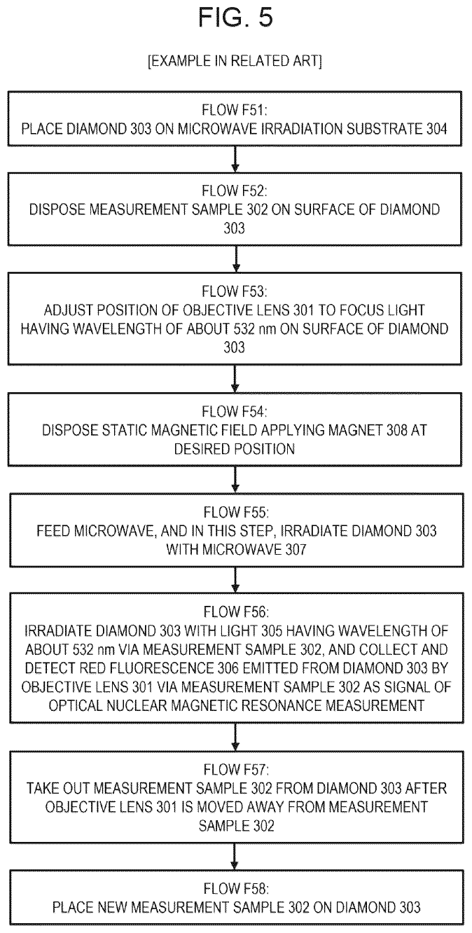

Next, FIG. 5 will be described. FIG. 5 is a flowchart showing an execution order of optical nuclear magnetic resonance measurement when the microwave irradiation substrate in the related art (that is, a microwave irradiation substrate not including the light transmission unit 105) is used.

In a flow F51, the diamond 303 is placed on the microwave irradiation substrate 304. In a flow F52, the measurement sample 302 is disposed on a surface of the diamond 303. In a subsequent flow F53, a position of the objective lens 301 is adjusted to focus the light having a wavelength of about 532 nm on the surface of the diamond 303. In a flow F54, the static magnetic field applying magnet 308 is disposed at a desired position.

In a flow F55, a microwave is fed, and in this step, the diamond 303 is irradiated with the microwave 307. Subsequently, in a flow F56, the diamond 303 is irradiated with the light 305 having a wavelength of about 532 nm via the measurement sample 302, and the red fluorescence 306 emitted from the diamond 303 is collected and detected by the objective lens 301 via the measurement sample 302 as the signal of the optical nuclear magnetic resonance measurement.

Subsequently, a procedure for performing the optical nuclear magnetic resonance measurement again while replacing the measurement sample 302 will be described. As in a flow F57, the measurement sample 302 is taken out from the diamond 303 after the objective lens 301 is moved away from the measurement sample 302. In a subsequent flow F58, a new measurement sample 302 is placed on the diamond 303. Thereafter, returning to the flow F53, the optical nuclear magnetic resonance measurement is performed.

As described above, the measurement sample 302 is limited to a form that transmits the light 305 having a wavelength of about 532 nm and the red fluorescence 306, for example, a form of a liquid or a thin film.

As described above, in the flow in the case of using the microwave irradiation substrate in the related art shown in FIG. 5, a form of the measurement sample 302 is limited (for example, in the flow F53 or the like). In addition, since it is necessary to adjust an optical disposition of the objective lens 301 when exchanging the measurement sample (for example, in the flows F53, F57 or the like), there is a high possibility that detection sensitivity varies for each measurement sample, which leads to a decrease in signal quality in the optical nuclear magnetic resonance measurement.

On the other hand, in a protocol of the optical nuclear magnetic resonance measurement as shown in FIG. 4 according to Embodiment 1, work of adjusting the objective lens 204 accompanying the exchange of the measurement sample 201 is unnecessary. In other words, the measurement sample 201 can be exchanged without moving the objective lens 204. A thickness of the measurement sample 201 is not limited to a working distance of the objective lens 204.

For example, the component analysis device according to Embodiment 1 can be configured to be capable of performing the optical nuclear magnetic resonance measurement on the measurement sample 201 having any thickness (for example, as shown in FIG. 2, a thickness of at least 0.1 nm, a thickness of at least 1 nm, a thickness of at least 10 nm, a thickness of at least 100 nm, a thickness of at least 1 μm, a thickness of at least 10 μm, a thickness of at least 100 μm, a thickness of at least 1 mm, a thickness of at least 10 mm, a thickness of at least 100 mm, or the like). In this manner, the limitation on the thickness of the measurement sample 201 is relaxed.

Further, the measurement sample 201 is not limited to one having a light transmitting property. For example, when the wavelength of the laser light is 532 nm, the optical nuclear magnetic resonance measurement can be performed on any measurement sample 201 having a reflectance of the laser light from 0% to 100% as shown in FIG. 2. That is, the reflectance of the laser light by the measurement sample 201 may be at least 1%, at least 3%, at least 10%, at least 30%, at least 50%, at least 90%, at least 99%, or the like. In this manner, the limitation on the material of the measurement sample 201 is relaxed.

In this manner, by implementing the disposition of the measurement sample 201, the diamond 202, the microwave irradiation substrate 101, and the objective lens 204 in this order using the microwave irradiation substrate 101 including the light transmission unit 105, the form of the sample that can be measured by the optical nuclear magnetic resonance can be expanded, a detection sensitivity variation for each measurement sample can be prevented, and the reliability of data in the optical nuclear magnetic resonance measurement can be improved.

Next, microwave emission properties of the microwave irradiation substrate 101 according to the present embodiment will be specifically described.

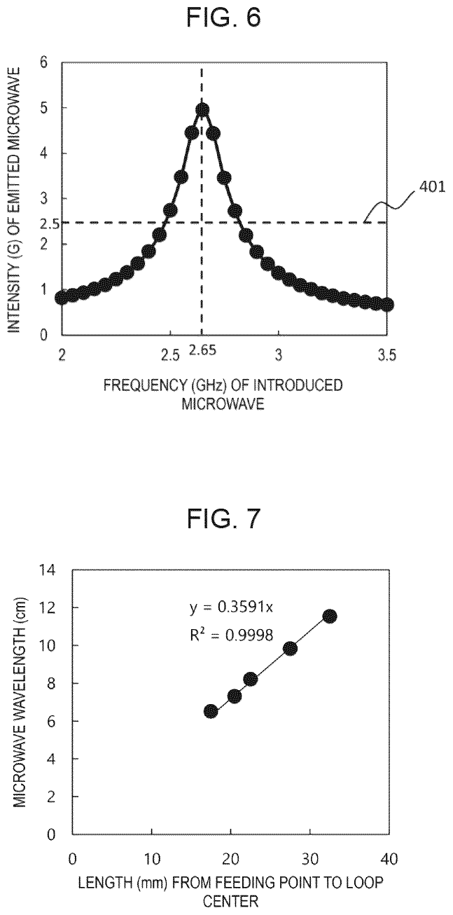

First, FIG. 6 will be described. FIG. 6 shows a relationship between a frequency of the microwave introduced into the microwave irradiation substrate 101 from the feeding point 106 via the electrode 103 and an intensity of the microwave emitted from the light transmission unit 105 of the microwave irradiation substrate 101 accordingly.

Here, as shown in FIG. 1, a length 601 from the feeding point 106 to a center of the loop 104 is 31.5 mm, a gap 602 between the two electrodes 103 and between the two interconnects 102 is 0.125 mm, a size 603 of the electrode 103 is 2 mm×3 mm, a thickness 604 of the interconnect 102 is 0.125 mm, an inner diameter 605 of the loop 104 is 0.75 mm, a size 606 of the microwave irradiation substrate 101 is 60 mm×7 mm, and a thickness 607 of the microwave irradiation substrate 101 is 0.2 mm.

It can be seen from FIG. 6 that the intensity of the microwave emitted from the light transmission unit 105 is maximized when the frequency of the introduced microwave is 2.65 GHz.

FIG. 6 shows a reference line 401 in the microwave intensity. The reference line 401 is a line indicating a minimum required value (2.5 Gauss) in the intensity of the microwave emitted from the light transmission unit 105 in the measurement using the optical nuclear magnetic resonance device according to the present embodiment. It can be seen from FIG. 6 that when the microwave irradiation substrate 101 is used, the intensity of the microwave emitted from the light transmission unit 105 greatly exceeds 2.5 Gauss indicated by the reference line 401.

Next, FIG. 7 will be described. FIG. 7 shows a relationship between a microwave wavelength and the length 601 from a feeding point to a loop center when the intensity of the microwave emitted from the light transmission unit 105 is maximized. When this graph is fitted with a linear line with zero intercept, a R² value is 0.9998, which is a value close to 1. That is, according to FIG. 7, it can be seen that the length 601 and the microwave wavelength when the intensity of the microwave emitted from the light transmission unit 105 is maximized have a proportional relationship of the zero intercept. This is because the microwave irradiation substrate 101 generates a standing wave of the microwave in the range of the length 601 when the microwave is introduced from the feeding point 106.

The microwave wavelength on the microwave irradiation substrate 101 is obtained by multiplying the wavelength of the microwave introduced from the electrode 103 by a wavelength shortening rate determined based on a dielectric constant and the thickness 607 of the microwave irradiation substrate 101. The frequency of the microwave is proportional to a reciprocal number of the microwave wavelength. Therefore, it can be seen that, in the microwave irradiation substrate 101, the frequency of the introduced microwave when the intensity of the microwave emitted from the light transmission unit 105 is maximized is determined only depending on the length 601, and the dielectric constant and the thickness 607 of the microwave irradiation substrate 101, and is not dependent on the gap 602, the size 603, the thickness 604, the inner diameter 605, and the size 606.

Therefore, when the dielectric constant and the thickness 607 of the microwave irradiation substrate 101 are constant, by changing the length 601, it is possible to change, to any value, the frequency of the introduced microwave when the intensity of the microwave emitted from the light transmission unit 105 is maximized.

Since the frequency of the microwave used for the optical nuclear magnetic resonance measurement is, for example, about 1 GHz to 5 GHz, the frequency of the microwave emitted from the light transmission unit 105 may also be, for example, about 1 GHz to 5 GHZ. Therefore, the length 601 and the dielectric constant and the thickness 607 of the microwave irradiation substrate 101 are not necessarily limited to the above-described values (the length 601 is 31.5 mm and the thickness 607 is 0.2 mm) as long as the standing wave of the microwave within this range is generated.

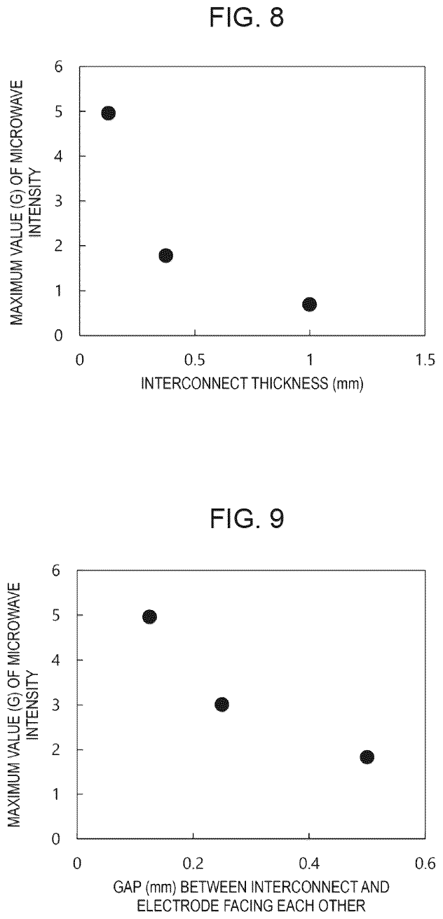

Next, FIG. 8 will be described. FIG. 8 is a graph showing a relationship between a maximum value of the intensity of the microwave emitted from the light transmission unit 105 and the thickness 604. Here, the length 601 is 31.5 mm, the gap 602 is 0.125 mm, the size 603 is 2 mm×3 mm, the inner diameter 605 is 0.75 mm, the size 606 is 60 mm×7 mm, and the thickness 607 is 0.2 mml.

It can be seen that the intensity of the emitted microwave increases as the value of the thickness 604 decreases. Therefore, the smaller the value of the thickness 604 is, the better, but it is preferable to set the thickness to such an extent that the interconnect is not damaged by Joule heat generated when the microwave is introduced.

Next, FIG. 9 will be described. FIG. 9 is a graph showing a relationship between the maximum value of the intensity of the microwave emitted from the light transmission unit 105 and the gap 602. Here, the length 601 is 31.5 mm, the size 603 is 2 mm×3 mm, the thickness 604 is 0.125 mm, the inner diameter 605 is 0.75 mm, the size 606 is 60 mm×7 mm, and the thickness 607 is 0.2 mm.

It can be seen that the intensity of the emitted microwave increases as the value of the gap 602 decreases. This is because, since a standing wave of the microwave is generated in the gap, an electric field between the facing interconnects 102 and the electric field between the facing electrodes 103 become stronger as the gap 602 is smaller. Therefore, the smaller the value of the gap 602, the better.

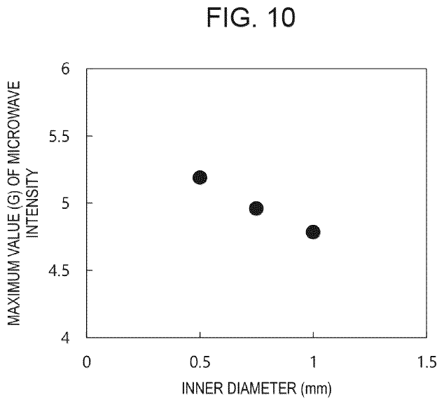

Next, FIG. 10 will be described. FIG. 10 is a graph showing a relationship between the maximum value of the intensity of the microwave emitted from the light transmission unit 105 and the inner diameter 605 of the light transmission unit 105. Here, the frequency of the microwave is 2.65 GHz, the length 601 is 31.5 mm, the gap 602 is 0.125 mm, the size 603 is 2 mm×3 mm, the thickness 604 is 0.125 mm, the size 606 is 60 mm×7 mm, and the thickness 607 is 0.2 mm.

It can be seen that the smaller the value of the inner diameter 605, the higher the intensity of the emitted microwave. This is because the electric field in the region of the light transmission unit 105 becomes stronger as the inner diameter 605 is smaller. Therefore, from the viewpoint of the intensity of the microwave, the smaller the inner diameter 605, the better. On the other hand, it is preferable to increase the inner diameter 605 to an extent of not blocking the light 205 having a wavelength of about 532 nm, which is emitted via the objective lens 204, transmitted through the microwave irradiation substrate 101, and focused on the diamond 202.

Although the value of the size 603 of the electrode 103 is freely set, in order to form the feeding point 106 on the electrode 103, it is necessary to connect the connector 207 on the electrode 103 via an interconnect from a microwave power generator. The size 603 is sufficiently a size to which the connector 207 can be connected. If another microwave introduction method such as wire bonding is selected without using the connector 207, the size 603 can be further reduced.

The value of the size 606 of the microwave irradiation substrate 101 is freely set, and is not necessarily limited to 60 mm×7 mm as long as the size includes a size of a circuit formed of copper therein.

An effect and structure of the microwave irradiation substrate 101 according to Embodiment 1 of the invention have been described above. From these descriptions, as the effect of the present embodiment, it is apparent that the disposition of the measurement sample, the diamond, the microwave irradiation substrate, and the objective lens can be implemented, the form of the measurement sample in the optical nuclear magnetic resonance can be expanded, and shortening of a measurement flow can improve the quality of the data in the optical nuclear magnetic resonance measurement.

According to the present embodiment, a microwave irradiation substrate that solves the problem in the related art is provided. That is, there is provided a microwave irradiation substrate for optical nuclear magnetic resonance which can be mounted on a device using the optical nuclear magnetic resonance method and which can implement the disposition of the measurement sample, the diamond, the microwave irradiation substrate, and the objective lens. Further, there is provided a microwave irradiation substrate for optical nuclear magnetic resonance capable of allowing the light of about 532 nm and the red fluorescence emitted from the NV center to transmit and capable of irradiating the diamond with a microwave. Further, there is provided a microwave irradiation substrate for optical nuclear magnetic resonance that does not require the adjustment of the objective lens every time the measurement sample is exchanged.

An example of the effect of the microwave irradiation substrate according to the present embodiment will be described. The microwave irradiation substrate according to the present embodiment implements a disposition of the measurement sample, the diamond, the microwave irradiation substrate, and the objective lens instead of a disposition of the objective lens, the measurement sample, the diamond, and the microwave irradiation substrate as in the related art. Accordingly, the light having a wavelength of about 532 nm emitted via the objective lens reaches the NV center in the diamond near the measurement sample without being blocked by the measurement sample. The red fluorescence emitted from the NV center can also reach the objective lens without being blocked by the measurement sample.

Further, the thickness of the measurement sample is not limited by a working distance of the objective lens, and a thicker measurement sample can be used. Further, since it is not necessary to change a height of the objective lens when exchanging the measurement sample, it is not necessary to adjust the objective lens for each measurement sample.

The combinations of the features disclosed in the invention and the present embodiment are not limited to the description in Claims.

### REFERENCE SIGNS LIST

101: microwave irradiation substrate
102: interconnect
103: electrode
104: loop
105: light transmission unit
106: feeding point
201: measurement sample
202: diamond
204: objective lens
205: light having wavelength of about 532 nm (laser light)
206: red fluorescence
207: connector
208: microwave
209: static magnetic field applying magnet
401: reference line in microwave intensity
601: length from feeding point to center of loop
602: gap between two electrodes and between two interconnects
603: size of electrode
604: thickness of interconnect
605: inner diameter of loop
606: size of microwave irradiation substrate
607: thickness of microwave irradiation substrate
All publications, patents, and patent applications cited in the present description are incorporated into the present description by citation as it is.

1. A component analysis device using an optical nuclear magnetic resonance phenomenon, the component analysis device comprising:
a diamond having an electron spin on an NV center that causes an electron spin resonance phenomenon;
a microwave irradiation substrate on which the diamond is disposed and which irradiates the diamond with a microwave;
an objective lens configured to irradiate the diamond with laser light and detect fluorescence emitted from the NV center in response to the irradiation with the laser light; and
a magnet configured to apply a static magnetic field to the NV center, wherein
the microwave irradiation substrate includes a light transmission unit configured to allow the laser light and the fluorescence to transmit.

2. The component analysis device according to claim 1, wherein
the diamond is configured to allow a measurement sample to be placed thereon.

3. The component analysis device according to claim 2, wherein
the measurement sample, the diamond, the microwave irradiation substrate, and the objective lens are disposed in this order.

4. The component analysis device according to claim 3, wherein
the measurement sample is exchangeable without moving the objective lens.

5. The component analysis device according to claim 1, wherein
a same region in the diamond is simultaneously irradiated with the laser light and the microwave.

6. The component analysis device according to claim 2, wherein
optical nuclear magnetic resonance measurement is performable on the measurement sample having a thickness of at least 0.1 nm.

7. The component analysis device according to claim 2, wherein
when a wavelength of the laser light is 532 nm, optical nuclear magnetic resonance measurement is performable on any measurement sample having a reflectance of the laser light from 0% to 100%.

8. The component analysis device according to claim 1, wherein
the microwave irradiation substrate includes a conductive portion, and
the conductive portion includes a pair of electrodes, an interconnect, and a loop.

9. The component analysis device according to claim 8, wherein
the loop has an arc-shaped portion.
